(19) United States
(12) Patent Application Publication
(10) Pub. No.: US 2026/0029497 A1
(43) Pub. Date: Jan. 29, 2026

(54) ADJUSTING A MEDIA SIGNAL TO AN MRI EXAMINATION VIA A GENERATIVE AI SYSTEM

(71) Applicant: Siemens Healthineers AG, Forchheim (DE)

(72) Inventors: Anja KUERTEN, Erlangen (DE); David GRODZKI, Erlangen (DE); Markus KLARHOEFER, Loerrach (DE)

(73) Assignee: Siemens Healthineers AG, Forchheim (DE)

(21) Appl. No.: 19/278,862

(22) Filed: Jul. 24, 2025

(30) Foreign Application Priority Data
Jul. 26, 2024 (EP) 24191056.1
Sep. 5, 2024 (DE) 10 2024 208 442.5

(51) Int. Cl. G01R 33/54; G01R 33/28

(52) U.S. Cl. CPC G01R 33/543; G01R 33/283

(57) ABSTRACT

A method for carrying out an MRI examination of a patient via an MRI system includes adjusting an examination parameter of the MRI examination to the patient via a control unit of the MRI system; providing the adjusted examination parameter via the control unit as an input parameter for a generative AI system, wherein the generative AI system is configured to generate a media signal as an output parameter in response to an input of the provided input parameter, wherein the generated media signal includes at least one of an audio track or a video track; receiving the generated media signal via a playback unit; and performing the MRI examination of the patient in accordance with the adjusted MRI examination parameter via the MRI system such that the received media signal is played via the playback unit for perception by the patient during the MRI examination.

### CROSS-REFERENCE TO RELATED APPLICATION(S)

The present application claims priority under 35 U.S.C. § 119 to European Patent Application No. 24191056.1, filed Jul. 26, 2024, and German Patent Application No. 10 2024 208 442.5, filed Sep. 5, 2024, the entire contents of each of which are incorporated herein by reference.

### FIELD

One or more example embodiments relates to a method for carrying out an MRI examination of a patient via an MRI system, to the MRI system, a computer-implemented method for providing a media signal via an AI system, the AI system and an associated computer program product and refers, such as, to the application of these technologies in order to improve the image quality and the diagnostic accuracy. This application deals with the problem that MRI examinations are often unpleasant and/or stressful for patients, in particular owing to the loud noises and/or the long duration of the MRI examination.

### RELATED ART

MRI examinations are generally very loud and are therefore perceived by many patients as being unpleasant. The main reason for the high noise emissions are the gradient coils of the magnetic unit of the MRI system, through which coils fast-changing currents typically flow during the MRI examination. The forces which are produced in the process result in mechanical distortions, vibrations and/or movements of the gradient coil. These forces are in part transferred to the remaining components of the MRI system, so the MRI system, in particular its tubes, acts like a loudspeaker. During the MRI examinations, noise levels of, in part, over 100 dBA are frequently reached, so it is imperative for the patient to wear hearing protection. Conventional media signals, in particular with audio tracks, are therefore played over loudspeakers or headphones for perception by the patient in order to distract and/or entertain the patients. It is typically not possible for the media signal to be perceived undisturbed due to the high volume of the gradient coils.

In past decades, methods have been developed with various hardware-based approaches and sequence or software techniques, which can make the examinations much quieter. In addition, there are approaches to fit the headphones with better sound insulation. Despite this, the MRI can still be perceived to be very loud.

DE 10 2014 222 496 A1 relates to a method of magnetic resonance imaging with a music-based gradient profile, comprising the following method steps: providing a magnetic resonance sequence and a piece of music, modifying the piece of music by taking into account at least one acoustic resonance parameter which characterizes at least one acoustic resonance frequency of the magnetic resonance device, wherein a modified piece of music is generated, adjusting a gradient profile of the magnetic resonance sequence using the modified piece of music, wherein an adjusted magnetic resonance sequence is generated, capturing magnetic resonance image data of the examination object via the adjusted magnetic resonance sequence. In other words, an attempt is made to adjust the MRI examination to a piece of music provided as a music track of a video signal in such a way that the MRI examination, ideally at the same noise emission levels, can be perceived as less of an unpleasant experience. Since the contrast of an MRI examination depends to a large extent on the selected repetition times, echo times and/or the echo spacing, the adjustment of the MRI examination to the piece of music which has been provided is typically often actually realistic only in a few cases and/or only with specific MRI examinations such as MR fingerprinting.

From WO 2010 018 534 A1 it is known to improve the noise generated by the gradient coils in an MRI device by playing back an appropriate piece of music, which matches the noise of the gradient coils in tempo and/or key, when a patient is subjected to an MRI examination. Embodiments are also known in the prior art in which music was generated to the sound of the noise emissions of an MRI system, see https://www.youtube.com/watch?v=e9593SnYwyo, wherein the media signal thus correlates tonally with noise emissions of the specified gradient profile, in particular the noise emissions are intermittently integrated in the audio track of the media signal.

Many patients also find MRI examinations unpleasant owing, inter alia, to the unfamiliar environment and/or narrow tube. In addition, many patients are nervous since the examination result can be critical to their further treatment. During the examination, media signals with a video track are conventionally already used which are intended to distract the patient from these unpleasant thoughts and feelings. This is effective particularly for children who ideally have to be sedated less frequently as a result. The media signals used are, for example, cartoons or documentaries or videos from a local video database and/or from Internet-based platforms. The patients themselves can frequently select a media signal in order to preferably provide them with the feeling of control over their environment. The problem with media signals which have been used until now is that they are not coordinated with the respective examination as a function of the patient.

This relates, for example, to the total duration of the media signal. Depending on the region of the body and/or patient, MRI examinations can last, for example, between 5 and 45 min. The exact total duration frequently changes during the performance of the MRI examination, in particular if, for instance, individual sequences of the MRI examination have to be repeated. It is therefore hardly possible to select a media signal for the patient in advance whose total duration substantially corresponds to the total duration of the MRI examination. This conventionally results in the MRI examination having finished before the media signal has finished, in particular the video track can be watched to the end, and/or the media signal has finished but the MRI examination has not yet finished. This can frequently irritate the patient, and can cause annoyance, particularly in the case of pediatric patients.

In particular, the previously used media signals are not coordinated in terms of content with the MRI examination. The media signals do not conventionally include items of information about the MRI examination, for example about the remaining time of the MRI examination.

Until now, the selection of suitable media signals has required the experience and/or finesse of the user of the MRI system, in particular the MTRA, who is caring for the patient and operating the MRI system. Depending on the preferences of the patient and/or the MRI examination, the user manually selects media signals which can be suitable in terms of duration and/or content. To reduce the effort, the user can frequently select a media signal which could be suitable for the largest possible number of patients. Alternatively, media signals are played which run for several hours during a plurality of MRI examinations and/or on a continuous loop. It is consequently conventionally possible to prevent the patient from becoming irritated when the total duration of the MRI examination and the total duration of the media signal are mismatched.

A further possibility for adjusting the media signals to the MRI examination is to overlay the video track of the media signal with items of information about the MRI examination. An infotainment system, for example, is known in which a progress bar can be faded-in on the video track in order to visualize the remaining time of the MRI examination.

### SUMMARY

One or more example embodiments provides an improved method for carrying out an MRI examination of a patient via an MRI system, the improved MRI system, an improved computer-implemented method for providing a media signal via an AI system, the improved AI system and an associated computer program product.

The is achieved at least by the features of the independent claims. Advantageous embodiments are described in the subclaims.

### BRIEF DESCRIPTION OF THE DRAWINGS

The invention will be described and explained in more detail below on the basis of the exemplary embodiments represented in the figures. Basically, substantially constant structures and units are designated in the following description of the figures by the same reference numerals as on the first occurrence of the respective structure or unit.

In the drawings:

FIG. 1 shows an inventive method for carrying out an MRI examination of a patient via an MRI system according to one or more example embodiments,

FIG. 2 shows a first exemplary embodiment of the method,

FIG. 3 shows a second exemplary embodiment of the method,

FIG. 4 shows a third exemplary embodiment of the method,

FIG. 5 shows a fourth exemplary embodiment of the method,

FIG. 6 shows a fifth exemplary embodiment of the method,

FIG. 7 shows a sixth exemplary embodiment of the method,

FIG. 8 shows a seventh exemplary embodiment of the method,

FIG. 9 shows an inventive method for providing a media signal via an AI system according to one or more example embodiments,

FIG. 10 shows an inventive AI system according to one or more example embodiments, and

FIG. 11 shows an inventive MRI system according to one or more example embodiments.

### DETAILED DESCRIPTION

An inventive method for carrying out an MRI examination of a patient via an MRI system comprises the following steps:
adjusting an examination parameter of the MRI examination to the patient via a control unit of the MRI system,
providing the adjusted examination parameter via the control unit as an input parameter for a generative AI system, wherein the generative AI system is configured to generate a media signal as an output parameter in response to an input of the provided input parameter and to provide the generated media signal for a retrieval, wherein the generated media signal depends on the adjusted examination parameter and comprises an audio track and/or a video track,
receiving the generated media signal via a playback unit,
carrying out the MRI examination of the patient in accordance with the adjusted MRI examination parameter via the MRI system in such a way that in the meantime the received media signal is played via the playback unit for perception by the patient.

One or more example embodiments provides improvements, in particular, in order to make the experience of the MRI examination more pleasant and more comfortable for the patient. By using the generative AI system with the examination parameter adjusted to the patient, a media signal which is dependent on the patient is generated, and this is played during the MRI examination. This media signal can advantageously comprise an audio track and/or a video track which is based on the individual characteristics of the patient. The patient is consequently preferably offered a pleasant distraction and/or the feeling of uncertainty is reduced. Overall, the invention contributes to improving the comfort and the satisfaction of the patient during the MRI examination.

The adjustment of the examination parameter to the individual patient also makes possible, in particular, a personalized MRI examination which can increase the wellbeing of the patient and improve the quality of the results of the examination. The use of the generative AI system to generate the patient-specific media signal can preferably increase the compliance of the patient during the MRI examination by creating a more pleasant environment which distracts from the stress of the MRI examination. Playing the media signal during the MRI examination can contribute, in particular, to a reduction in movement artifacts since the patient is entertained and reassured by the media signal, and this can result in a better image quality.

The media signal, which is part of the generated output parameter or forms the generated output parameter, advantageously depends on the adjusted examination parameter and on the patient. Consequently, a close connection ideally develops between the individual needs of the patient and the performance of the MRI examination.

The inventive MRI system according to one or more example embodiments has
a magnetic unit, wherein the magnetic unit comprises a main magnet and at least one gradient coil,
the control unit
and, in particular, a playback unit, wherein the MRI system is embodied to carry out the inventive method according to one or more example embodiments.

The design of the MRI system in order to carry out the inventive method according to one or more example embodiments makes a seamless integration of imaging and patient-oriented functions possible, and this can advantageously increase the system efficiency and ease of use. The control unit, which is specifically configured for the method, can make it possible to adjust the imaging parameters to the patient, and this preferably results in a reduction in the examination time and an optimization of the workflow.

The inventive computer-implemented method according to one or more example embodiments for providing a media signal via an AI system comprises the following steps:
receiving an examination parameter of an MRI examination of a patient as an input parameter,
generating a media signal as an output parameter in response to an input of the input parameter,
providing the generated media signal for retrieval, wherein the generated media signal depends on the adjusted examination parameter and comprises an audio track and/or a video track.

An inventive AI system according to one or more example embodiments has
an input interface for receiving an input parameter,
a computer unit for generating an output parameter as a function of the received input parameter by applying a generative AI model to the input parameter,
an output interface for providing the generated output parameter, wherein the AI system is embodied, in particular trained, to provide the media signal. The AI system can be developed, in particular, as in the following embodiments.

The input interface typically makes a flexible adjustment of the AI system to various input parameters possible, and this increases the applicability to a broad palette of clinical scenarios. The computer unit, which is specifically trained for the generation of media signals as the output parameter, can improve the diagnostic efficiency, in particular when the patient feels better during the MRI examination. The output interface facilitates the integration of the data generated by the AI system in clinical workflows, and this preferably supports decision-making and patient care.

The term “MRI system” refers here to the medical device which is suitable and/or used for performing the MRI examination and comprises, in particular, a magnetic unit, a control unit and possibly an AI system. The MRI system can be referred to, in particular, as an MRI scanner.

The term “gradient coil” refers here to a coil in the MRI system, which is used to generate magnetic gradients. These gradients make it possible to spatially encode signals during the MRI examination.

MRI, also known as magnetic resonance imaging, is, in particular, a medical imaging technique which uses overlaying magnetic fields and radio waves generated by the magnetic unit and/or the at least one gradient coil to generate detailed images of the patient. MRI examinations are especially useful for examining soft tissues of the patient. Basically, the use of MRI examinations on objects instead of patients is conceivable. In contrast to X-rays or CT scans, the MRI system does not use any ionizing radiation when performing the MRI examination and is therefore a safe and non-invasive method for examining the patient.

The term “patient” refers here to the individual to which the MRI examination is adjusted and who perceives the generated media signal during the MRI examination. During an MRI examination, the patient is pushed into a tube which is surrounded by the magnetic field. This magnetic field orients the hydrogen atoms in the body of the patient. Radio waves are then sent through the body, and these disrupt the orientation of the hydrogen atoms. When the radio waves are switched off, the atoms return to their original orientation according to the material-specific T1 and T2 times and in the process emit signals which are captured by a receive unit of the MRI system. These signals are processed, in particular, by a computing unit to generate material-differentiated images of the body.

MRI examinations can be performed in different planes in order to examine different parts of the body. The images can also be created in 3D in order to make an even more detailed representation of the body of the patient possible. MRI examinations are particularly useful for diagnosing diseases of the brain, the spinal cord, the joints, liver and other organs. They can also be used to identify tumors, inflammation, infections and other diseases.

MRI examinations are painless and/or, as a rule, last between 5 and 45 minutes. During the examination, the patient has to lie still to prevent movement artifacts. In some cases, a contrast agent can be injected in order to make specific regions of the body more visible. After the examination, the images can be evaluated, in particular by a radiologist, in order to make a diagnosis and/or track the course of a disease.

The term “MRI examination” refers here to the process of performing an MRI examination in which at least one image of at least part of the body of a patient is generated in order to obtain, in particular, diagnostic items of information about the at least one part of the body. The MRI examination is frequently called a scan.

The term “MRI sequence” refers here to the process of capturing specific signals during an MRI examination. These specific signals are used to generate correspondingly configured images of the body of the patient and/or to obtain diagnostic items of information about the patient.

The MRI examination typically takes place in accordance with an MRI examination protocol. The MRI examination protocol comprises, in particular, at least one MRI sequence. The MRI examination protocol can comprise, in particular, a plurality of MRI sequences which are typically successively carried out in an optimally unbroken sequence.

An MRI sequence, typically each MRI sequence, is carried out, in particular, in accordance with its examination parameter(s). Customarily, the MRI examination is performed in accordance with a large number of examination parameters of the one MRI sequence or of the plurality of MRI sequences. The MRI sequences of the MRI examination protocol can differ in at least one examination parameter, in particular in an examination volume and/or in a contrast and/or a resolution and/or an orientation and/or in an instant of administering of contrast agent. If two MRI sequences differ solely in the instant of administering the contrast agent, the examination parameters of these two MRI sequences are not identical. If two MRI sequences differ solely in an absolute starting instant of the first MRI sequence, the examination parameters of these two MRI sequences are typically identical. The absolute starting instant is, in particular, a time.

The total duration of the MRI examination typically corresponds to the total duration of the MRI examination protocol. The total duration of the MRI examination is typically defined as the period between the starting instant of the first MRI sequence of the MRI examination protocol and the end instant of the final MRI sequence of the MRI examination protocol. In particular, a preparatory period or follow-up period, in particular for positioning the patient on the patient couch and/or moving the patient couch, with the patient supported thereon, into or out of the tube of the MRI system is typically not part of the total duration of the MRI examination.

Typically, the examination parameters can be divided into examination parameters which can be adjusted individually for each patient and those which cannot be adjusted individually for each patient. An adjustment of an examination parameter which can be adjusted individually for each patient can result, for example, in an adjustment of an examination parameter, which cannot be adjusted individually for each patient, automatically carried out by the control unit, and vice versa. It is conceivable that the control unit automatically adjusts a further examination parameter which can be adjusted individually for each patient and/or a further examination parameter which cannot be adjusted individually for each patient once the examination parameter is adjusted or has been adjusted to the patient. Typically, an examination parameter which can be adjusted individually for each patient is adjusted to the patient.

The examination parameters can typically be divided into sequence parameters and workflow parameters. Sequence parameters relate, in particular, to how the magnetic fields and/or the radio waves are generated and/or set and/or varied via the MRI system. Such an examination parameter can comprise, for example, a repetition time, an echo time and/or an echo spacing of the MRI examination. Workflow parameters relate, in particular, to behavior parameters, which are intended to follow the patient over at least part of the total duration of the MRI examination to increase the quality of the generated images. Such an examination parameter can comprise, in particular, one or more instant(s) and/or the total or a remaining duration for the patient to remain lying down, hold their breath, stay still and/or relax.

The examination parameters can be, in particular, variable over time, in particular be resolved over time and/or vary over time, for example in their sequence and/or intensity over time. The sequence over time can comprise a large number of different or identical repetition times, echo times and/or echo spacings. Alternatively or in addition, the sequence over time can comprise one or more instant(s) and/or a total or remaining duration to remain lying down, breath-hold, stay still and/or relax. It is conceivable that the intensity of the examination parameters, which are variable over time, changes, for example a distinction is made between shallow and normal breathing. Alternatively or in addition, intensities of the large number of radio waves can differ.

The term “control unit” refers here to a component of the MRI system, which serves, in particular, to adjust the examination parameter to the patient and provide it as an input parameter for the AI system. The control unit can comprise, in particular, a computing unit and/or a logic module to execute program code which map the adjustment of the examination parameter, the provision of the adjusted examination parameter, the reception of the generated media signal, the performance of the MRI examination and/or playing of the received media signal. The control unit can also comprise a memory unit in order to store and/or buffer and/or retrieve the adjusted examination parameter and/or the generated media signal.

The control unit can be a local component of the MRI system, which is physically located inside the MRI examination space or in a control space with a view of the MRI control space. The control unit can alternatively be a remote component of the MRI system, which can be positioned, for example, in a server room of the operator of the MRI system and/or in a Cloud.

In order to adjust the examination parameter, the control unit can comprise input means, such as a keyboard, a computer mouse and/or a screen with or without touch-sensitive surface (touchscreen) and/or a sensor for capturing the patient. The examination parameter can be adjusted by a user of the MRI system and/or semi-automatically or completely automatically. It is conceivable that some of the examination parameters are automatically adjusted and other examination parameters are adjusted by the user. Adjusting the examination parameter means, in particular, changing and/or setting the examination parameter.

The control unit can comprise, in particular, an interface for providing the adjusted examination parameter. The adjusted examination parameter can be transferred, for example, from the interface of the control unit to the input interface of the AI system. It is conceivable that the input interface of the AI system retrieves the adjusted examination parameter from the control unit, in particular from the interface of the control unit. The interface can be, in particular, a network interface, in particular an Ethernet, a WIFI or mobile Internet interface, and/or a data interface, to which further units, in particular the AI system and/or a computing unit, has access.

The control unit can typically provide the adjusted examination parameter in a file format and/or in a specific signal form. The control unit and/or the MRI system typically has a conversation unit in order to convert the adjusted examination parameter into the file format and/or the specific signal form.

Providing the adjusted examination parameter as an input parameter for the generative AI system means, in particular, that an input parameter is provided for the generative AI system, wherein the input parameter comprises at least the adjusted examination parameter. The adjusted examination parameter can be provided immediately after the adjustment of the examination parameter, in particular before a further examination parameter of the MRI examination is adjusted. Alternatively it is conceivable that the adjusted examination parameter is only provided when all necessary examination parameters of the MRI examination are adjusted, in particular the MRI examination can be performed therefore.

The adjusted examination parameter is typically automatically provided. Alternatively or in addition, it is conceivable that the user of the control unit triggers the provision of the adjusted examination parameter, in particular by activation of a key or a button.

Providing the adjusted examination parameter via the control unit as an input parameter for the generative AI system can also comprise triggering of an application of the generative AI model of the AI system to the adjusted examination parameter as an input parameter. Triggering of the application corresponds, in particular, to the beginning of the generation of the media signal via the AI system.

The term “AI system” refers here to a generative system which generates an output parameter on the basis of the provided input parameter. It is configured to generate the media signal as a function of the input parameters. The AI system is a system which uses artificial intelligence (AI) to generate output parameters on the basis of input parameters. It comprises, in particular, an input interface, a computer unit and an output interface. Typically, the AI system is network-based.

The AI system can, in particular, be Internet-based, for example Cloud-based. The AI system can be made available, for example, by a different provider to the provider and/or the manufacturer of the MRI system. The AI system can be, for example, chargeable per application to the adjusted examination parameter. The AI system can alternatively be made available as part of a computing center of the provider of the MRI system and/or of the manufacturer of the MRI system and/or as part of the control unit.

The input interface is embodied to receive at least one input parameter which is provided as an input for the AI system. This or these input parameter(s) can include various items of information which are relevant to the generation of the output parameter. In particular, the adjusted examination parameter is the or one of the input parameter(s). Receiving the input parameter can correspond to inputting the input parameter insofar as the input parameter is automatically input after the input parameter has been received.

The term “computer unit” refers, in general, to a component of a system, in particular of the AI system and/or of the MRI system and/or the control unit, which is capable of carrying out calculations and processing operations. In this context the computer unit refers to the unit which is responsible for the generation of the output parameter as a function of the input parameters.

The computer unit is embodied to generate the output parameter as a function of the received input parameter. This occurs by the application of a generative AI model to the input parameter(s). This new data resembles the training data, but is not identical to it. The generative AI model is an artificial intelligence model which is capable, in particular, of generating new data which depends on the input data. The term “intelligence” refers here to the ability of the AI system to generate an output parameter on the basis of the input parameter, which adjusts the media signal accordingly. The term “response” refers here to the fact that the generative AI system generates an output parameter in response to the input parameter.

Examples of generative AI models are Generative Adversarial Networks (GANs), Variational Autoencoders (VAEs) and/or autoregressive models. Generative AI models learn from a large volume of training data in order to capture the underlying probability distributions of the data. As soon as the model is trained, it can generate new data by drawing random samples from the learnt distribution.

The generative AI model can be embodied to generate a media signal from scratch and/or retrieve and adjust an older media signal in order to generate the output parameter. The older media signal can retrieve, for example, by the AI model from a database. Basically, the generated media signal can be the older media signal for a further generation. The database can be, in particular, network-, Internet- or Cloud-based.

The AI model is configured, in particular, in such a way that the generated output parameter depends on the input parameter. The dependence can denote a resemblance and/or an adjusted quality. In other words, the generated output parameter resembles the input parameter and/or the generated output parameter is adjusted to the input parameter. The dependence can relate to only part of the output parameter, in particular only one characteristic or a few characteristics of the output parameter. The term “dependence” refers here to the fact that the generated media signal depends, in particular, on various factors, such as the adjusted examination parameter and/or the patient.

The dependence can be set, in particular, in accordance with an instruction parameter. The instruction parameter can be provided, for example, in addition to the adjusted examination parameter. Alternatively or in addition, the AI system can be pre-configured in accordance with the instruction parameter. The instruction parameter relates, in particular, to a specification in which the dependence between output parameter and input parameter should exist. In particular, the instruction parameter can specify the degree of dependence and/or the characteristic part of the dependence. Typically, the degree of dependence is more than 0% and/or less than 100%. The instruction parameter can be set, for example, by the user and/or the patient. It is sometimes conceivable that the dependence is set in accordance with a plurality of instruction parameters, with one instruction parameter being specified and/or set by the user and a further instruction parameter being specified and/or set by the patient.

The generated media signal comprises, in particular, an audio track and/or a video track. If the generated media signal comprises the audio track and the video track, the audio track and the video track are typically synchronized in terms of time and/or content. The term “audio track” refers here to the acoustic part of the media signal. If the generated media signal does not comprise a video track, the generated media signal is, in particular, a music signal. The term “video track” refers here to the visual part of the media signal. If the generated media signal does not comprise an audio track, the generated media signal is, in particular, a silent film signal.

The output interface is embodied to provide the generated output parameter. This output parameter includes, in particular, the results due to the application of the generative AI model to the input parameter(s) by the AI system.

Providing the adjusted examination parameter via the control unit as an input parameter for the generative AI system can also comprise a standby state of the control unit and/or of the MRI system for receiving the generated media signal via the MRI system. The standby state for receiving can comprise, in particular, the start of a shutdown period (timeout), with the generated media signal being received via the MRI system typically within the shutdown period. If the generated media signal is not received within the shutdown period, the control unit can provide, for example, the adjusted examination parameter via the control unit as an input parameter for the generative AI system again and/or output an error signal to the user.

The generated media signal is typically received via the playback unit before performance of the MRI examination and playing of the received media signal. It is conceivable that performance of the MRI examination has begun if the generated media signal is received via the playback unit. Playing of the received media signal can begin without a break after the generated media signal has been received and/or at the beginning of performance of the MRI examination and/or with a delay period which can be specified.

The control unit and/or the playback unit and/or the MRI system can have an interface for receiving the generated media signal. In particular, a media unit can have the interface for receiving the generated media signal. In particular, the media unit and/or the control unit and/or the MRI system and/or the playback unit can receive the generated media signal. Reception of the generated media signal via the playback unit can comprise that the generated media signal is received via the control unit and/or the MRI system and/or the media unit before reception via the playback unit. The generated media signal can be transferred, for example, from the output interface of the AI system to the interface of the control unit and/or the playback unit and/or the MRI system and/or the media unit. It is conceivable that the interface of the control unit and/or the playback unit and/or the MRI system and/or the media unit retrieves the generated media signal from the output interface of the AI system.

The interface can be, in particular, a network interface, in particular an Ethernet, a WIFI or mobile Internet interface, and/or data interface, to which further units, in particular the AI system and/or a computing unit, has access. The interface can, in particular, be the same interface as for providing the adjusted examination parameter, or a further interface.

The media unit can be part of the control unit and/or the playback unit and/or the MRI system. Alternatively it is conceivable that the media unit is not part of the control unit and/or the playback unit and/or the MRI system, but is an independent component or part of the AI system or is Cloud-based or network-based. The media unit and/or the control unit and/or the MRI system can be configured to store and/or buffer and/or retrieve the generated media signal. The media unit can be configured, in particular, to transmit the generated media signal to the playback unit and/or to stream it and/or play it via the playback unit. The media unit can comprise, in particular, a media server which is configured to store and/or buffer and/or retrieve the generated media signal and/or to stream and/or transmit it to the playback unit.

Streaming of the generated media signal means, in particular, that only part of the media signal, which is sufficient for what is currently being played, in particular the current playback, is transmitted to the media unit and/or the playback unit, and not the entire media signal. Streaming makes faster and more efficient transmission and playback of the media signal possible without the media signal having to be transmitted in its entirety. Streaming can take place in real time or with a slight delay. In this case, the streaming unit forms at least part of the playback unit.

Alternatively or in addition, the media unit can transmit the generated media signal in its entirety to the playback unit. This means that the media signal is only played if it has been transmitted in its entirety from the media unit to the playback unit. The entire transmission of the media signal requires, in particular, more time and/or storage space than streaming, but advantageously makes uninterrupted playback possible.

The playback unit and/or the media unit and/or the control unit and/or the MRI system can be embodied to pause and/or start the playing of the received media signal. Basically it is conceivable that the playback unit and/or the media unit is configured for playing the received media signal on a continuous loop.

After the generated media signal has been received via the MRI system, the control unit, in particular, can output a ready signal in order to acknowledge reception of the generated media signal. If the MRI examination can be performed, an absolute instant can be defined, for example by reception of the generated media signal, at which instant performance of the MRI examination and/or playing of the generated media signal begins. In particular, performance of the MRI examination and/or playing of the received media signal can be triggered by reception of the signal.

The term “performance of the MRI examination” refers here to the practical implementation of the MRI examination using the described steps and parameters in accordance with the adjusted examination parameter. Performance of the MRI examination of the patient comprises, in particular, an activation of the magnetic unit and/or the at least one gradient coil and/or an emission of the radio waves via the MRI system. The performance of the MRI examination typically does not comprise a movement of the patient couch.

Ideally, the MRI examination is performed and the received media signal played simultaneously and/or with a maximum overlap time-wise. Basically it is conceivable that the MRI examination begins before the received media signal is played. Alternatively, playing of the received media signal can begin before the MRI examination is performed.

Preferably, performance of the MRI examination finishes at the same time as playing of the received media signal. Basically it is conceivable that performance of the MRI examination finishes before the received media signal has finished playing. Alternatively, the received media signal can finish playing before performance of the MRI examination has ended.

Playing of the received media signal via the playback unit comprises, in particular, playing back of the received media signal via the playback unit. Playing of the received media signal preferably starts with the beginning of the received media signal and/or finishes with the end of the received media signal. Basically it is conceivable that playing of the received media signal starts several seconds or, for example, minutes after the start of the received media signal and/or finishes several seconds or, for example, minutes before the end of the received media signal. The several seconds is, in particular, at most 10s, preferably 2s.

Playing can comprise fading-in the video track. Playing can comprise outputting the audio track. The video track is typically faded-out and/or the audio track is muted before or after playing.

In order to fade-in the video track, the playback unit can comprise a projection unit and/or a display unit, via which the video track is played. The projection unit can comprise, for example, a projector and/or a projection surface. The projection surface can be a screen and/or an inner wall of the bore of the MRI system.

In order to output the audio track, the playback unit can comprise an audio unit. The audio unit can comprise a loudspeaker and/or headphones.

The playback unit is, in particular, MRI-compatible. The playback unit is configured, in particular, such that the fading-in of the video track and/or outputting of the audio track can be perceived by the patient. Perception by the patient means, in particular, hearing the audio track and/or viewing the video track. The term “perception” refers here to the detection and processing of the media signal by the patient.

Hereinafter, in particular the wording “so” is used to emphasize the dependence of the specific generation of the output parameter on the respective input parameter. The AI system is embodied or trained, in particular, in such a way as to take this dependence into account.

In one embodiment, the method also comprises the following steps: receiving an item of preference information individual to the patient via the control unit and providing the received item of preference information individual to the patient as a further input parameter in addition to the adjusted examination parameter for the generative AI system, so the generated media signal also depends on the item of preference information individual to the patient. Providing the received item of preference information as a further input parameter for the generative AI system means, in particular, that at least one input parameter is provided for the generative AI system, wherein the at least one input parameter comprises the adjusted examination parameter and the item of preference information individual to the patient. Taking account of an item of preference information individual to the patient makes an even greater personalization of the media signal possible, and this can further increase patient satisfaction and relaxation. The incorporation of the preferences of the patient makes it possible for the generative AI system to generate content which is tailored specifically to the interests and needs of the patient, and this improves the effectiveness of the distraction during the examination. The adjustment of the media signal to the preferences of the patient can promote the cooperation of the patient and thus reduce the probability of repeat scans owing to patient movements. The item of preference information individual to the patient can, in particular, be provided as an instruction parameter and/or be input into the AI system in order to set and/or change the dependence between the adjusted examination parameter and the generated media signal. The item of preference information individual to the patient typically relates, in particular solely, to a content of the media signal and/or not to a total duration of the media signal.

In one embodiment, the patient is provided with a plurality of media signal content types for selection by the patient, wherein the item of preference information individual to the patient comprises the media signal content type selected by the patient. The selected media signal content type is typically limited to an instruction parameter which relates solely to the content of the media signal. Media signal content types can be, for example, different styles of music and/or film genres and/or precast media signals. It is conceivable that as a media signal content type the patient selects a precast media signal, for example a video from an Internet-based platform, with the precast media signal being used as an instruction parameter in such a way that the generated media signal is based on the precast media signal. In this case, the context of the generated media signal and the context of the precast media signal is typically identical and/or similar at least for a fraction of time. In other words, according to the embodiment, the generated media signal is solely an adjusted precast media signal, with the adjustment depending on the adjusted examination parameter. For selection by the patient, the control unit can have an input means and/or be connected to an input means which the patient uses to select one of the plurality of media signal content types. Ascertainment of the items of preference information by the patient themselves increases the patient's engagement and control over the examination process, and this can result in increased satisfaction. Direct input of the preferences by the patient can improve the accuracy of the captured items of information and thus increase the relevance of the generated media signal to the patient. Use of an input means to capture the preferences can make the process of personalization of the media signal more efficient and shorten the setup time for the MRI examination.

In one embodiment, the adjusted examination parameter is variable over time, so the audio track and/or the video track of the generated media signal are synchronized rhythmically and/or harmonically and/or in terms of image content via the AI system with the examination parameter which is variable over time. The synchronization of the audio track and/or video track of the media signal with the examination parameter of the MRI examination can advantageously help the patient prepare for the examination and follow the instructions better. The synchronization of the media signal with the examination parameter can improve the coordination between the MRI system and the patient, and this results in a more efficient examination. The coordination of the media signal with the examination parameter which is variable over time can contribute to a reduction in the number of necessary interactions between the user and the patient, and this can decrease the workload of the user. Rhythmic synchronization means, in particular, that changes in acoustic level and/or acoustic frequency and/or image content are coordinated with a clock of the noise emissions of the MRI examination, which is incorporated, in particular, by the examination parameter. Harmonic synchronization means, in particular, that in particular the acoustic frequencies of the audio track are coordinated with the frequencies of the noise emissions of the MRI examination. Image content synchronization means, in particular, that image contents of the video track are coordinated with the intensity of the noise emissions and/or the remaining duration of the MRI examination. For example, the video track could show an individual who is climbing a mountain. In this case, the generated media signal is generated by the AI system in such a way that the mountain climber reaches the peak when the MRI examination has finished. The synchronization can mean, in particular, that the remaining duration of the MRI examination is translated into a narrative arc of suspense.

In one embodiment, the generated media signal comprises a video track, with the video track comprising a graphical representation of an individual for interaction with the patient such that during performance of the MRI examination, items of information are played to the patient via the represented individual as a function of the examination parameter. The graphical representation of the individual in the video track, which interacts with the patient, can supply clear and comprehensive instructions, and this can improve patient compliance during the examination. The provision of items of information as a function of the sequence parameters by the represented individual can reduce the need for verbal communication and thus minimize disruptions for the patient during the MRI examination. The visual guidance by way of the video track can improve the comprehensibility and observance of the instructions, in particular in the case of patients who have difficulties with auditive instructions, and this can contribute to a better image quality and a more efficient examination. The graphical representation of the individual can be, in particular, an avatar. The interaction of the graphical representation with the patient can be one-sided insofar as items of information are provided via the graphical representation, which the patient can perceive, but not vice versa. The interaction of the graphical representation can take place such that the items of information are also played as part of the audio track and meanwhile the individual is graphically represented speaking and/or the items of information are graphically represented in gestures and/or modes of behavior of the individual, for example to remain lying down, breath-hold, stay still and/or relax.

In one embodiment, the adjusted examination parameter comprises a repetition time, an echo time and/or an echo spacing of the MRI examination, so the generated media signal depends on the repetition time and/or the echo time and/or the echo spacing. The specification of examination parameters such as repetition time, echo time and/or echo spacing makes precise control of the image quality and/or the contrast ratios possible, and this results in improved diagnostic significance of the MRI images.

In one embodiment, the examination parameter comprises one or more instant(s) and/or a total or remaining duration for the patient to remain lying down, hold their breath, stay still and/or relax, so the generated media signal depends on the one or more instant(s) and/or the total or remaining duration to remain lying down, breath-hold, stay still and/or relax. The definition of one or more instant(s) to remain lying down, breath-hold, stay still and/or relax contributes to the reduction of movement artifacts, and this enhances the image quality and increases diagnostic accuracy of the MRI examination. The coordination of the patient actions during the MRI examination improves the comfort for the patient and can reduce the need for repeated scans, and this saves time and costs. The term “to remain lying down” refers here to the condition in which the patient should not get up from the patient couch during the MRI examination in order to begin performance of and/or to be able to conclude the MRI examination. The term “breath-hold” refers here to the condition in which the patient should hold their breath during the MRI examination in order to minimize movement artifacts. The term “stay still” refers here to the condition in which the patient should remain still during the MRI examination, in particular independently of holding their breath, to minimize movement artifacts. The term “relax” refers here to the condition in which the patient should typically be at ease in breaks between MRI sequences and/or can move unchecked during the MRI examination, because such movements do not impair the image quality and/or the MRI examination.

In one embodiment, the examination parameter comprises a total duration of the MRI examination, so the total duration of the generated media signal substantially corresponds to the total duration of the MRI examination. In this case, the received media signal substantially finishes playing with the end of the received media signal and the end of performance of the MRI examination. Substantially means, in particular, a deviation between the absolute end instants of the media signal which has been played and the performance of the MRI examination of at most up to 30s, preferably 10s, particularly advantageously 2s. Advantageously, the absolute end instant of the media signal that has been played corresponds to the absolute end instant of performance of the MRI examination. It is particularly advantageous if the received media signal starts playing at the beginning of the received media signal and the beginning of performance of the MRI examination and finishes at the end of the received media signal and the end of performance of the MRI examination. The specification of a total duration of the MRI examination makes accurate planning and scheduling of examinations possible, and this results in a more efficient utilization of the MRI system. Coordinating the duration of the media signal with the examination duration can improve the patient experience by shortening the perception of the examination time and the patient being better informed and entertained. The patient is advantageously less irritated as a result. In particular, an alignment of the total durations results in less upset, particularly in the case of pediatric patients.

In one embodiment, the generated media signal comprises an audio track, wherein the examination parameter comprises a gradient profile of at least one gradient coil of a magnetic unit of the MRI system, so the audio track of the generated media signal is rhythmically and/or harmonically synchronized with noise emissions of the gradient profile in such a way that the noise emissions are overlaid or integrated by the media signal which has been played. The noise emissions, in particular the frequency profiles, can correspond to the Fourier transforms of the gradient profiles and can thus advantageously be predicted or be calculated in advance to a certain extent. The synchronization of the generated media signal with the noise emissions of the gradient profile can reduce the noise and/or stress level for the patient in that disturbing noises are overlaid or integrated in a harmonious sound. The improved patient acceptance due to a more pleasant acoustic environment can reduce the movement artifacts and enhance the image quality, and this contributes to a more efficient diagnosis. The gradient profile is specified, in particular, by a repetition time, an echo time and/or an echo spacing of the MRI examination.

In one embodiment, after the beginning of the performance of the MRI examination, an examination parameter is re-adjusted, wherein the examination parameter which has been re-adjusted is provided as an input parameter for the generative AI system, wherein the generative AI system is configured to adjust the generated media signal to the examination parameter which has been re-adjusted in response to an input of the provided examination parameter which has been re-adjusted in order to generate an adjusted media signal and provide it for retrieval, wherein the adjusted media signal depends on the examination parameter which has been re-adjusted, and is based on the generated media signal, wherein playing is continued with the adjusted media signal as a replacement for the generated media signal for the remaining time of the performance of the MRI examination. The re-adjustment of the examination parameter after the beginning of the MRI examination and the corresponding adjustment of the media signal by the generative AI system make a flexible response to altered examination conditions possible, and this improves the image quality and examination efficiency. The provision of an adjusted media signal, which depends on the re-adjusted examination parameter and thus the patient, can personalize the patient experience and increase comfort during the examination, and this promotes the cooperation of the patient and improves the quality of the results. The continuation takes place, in particular, uninterrupted, so the patient advantageously does not perceive that, instead of the generated media signal, the adjusted media signal is being played. In other words, when the generated media signal is being played, the switch to the adjusted media signal is preferably optimally uninterrupted. The re-adjusting of an examination parameter can relate to the examination parameter which has already been adjusted previously or a different examination parameter. In particular, an examination parameter of an MRI sequence which has already begun, but is not yet concluded, or which has already been concluded, or which has not yet begun can be adjusted. The re-adjusting of an examination parameter comprises, in particular, a repetition of an MRI sequence of the MRI examination which has already been concluded. That the adjusted media signal is based on the generated media signal means, in particular, that the adjusted media signal is generated starting from the content of the generated media signal, so the context of the generated media signal continues in the adjusted media signal at least for a certain duration of several seconds, advantageously minutes. The context of the media signal relates, in particular, to a content-related portion which is characterized by harmonies and/or rhythms and/or image contents. Compared to generation of the generated media signal, the media signal content type is typically not altered, in particular in the case of an adjusted media signal.

In one embodiment, at least one gradient coil of the MRI system is energized as a playback unit to play the audio track of the media signal during performance of the MRI examination over at least part of the total duration of the generated media signal. In other words, the playback unit of the MRI system comprises, in particular, the at least one gradient coil. The use of the gradient coil to play the media signal can reduce the need for additional hardware, and this results in a cost saving and a simplified system configuration. This embodiment is advantageous, in particular, if the generated media signal is rhythmically and/or harmonically synchronized with the noise emissions of the gradient profile. The at least one part of the total duration can relate, in particular, to those fractions of time of the total duration in which no signals of the MRI images have to be captured. Alternatively or in addition, it is conceivable that the at least one gradient coil is used as a playback unit for the total duration of the media signal.

In one embodiment, the MRI system also has the AI system. The expansion of the MRI system by the AI system can improve the diagnosis accuracy by way of advanced image analysis and pattern recognition, in particular without having to communicate via an Internet connection of the MRI system. The AI system can contribute to the optimization of the imaging parameters in real time, and this can result in an individually adjusted patient examination and improved image quality.

An inventive computer program product according to one or more example embodiments has program code to carry out the inventive method according to one or more example embodiments when the computer program product is executed in the computing unit.

The computer program product makes simple and fast implementation of the method possible in existing AI systems and/or MRI systems, and this facilitates the updating and expansion of the system functionality. The ability to be directly loaded in the memory of the computing unit ensures a high level of compatibility and ease of use, and this promotes acceptance in clinical practice. The execution of the program code can result in a standardized application of the method, and this improves the reproducibility of the results and the comparability of the data across various locations.

The computer program product can be a computer program or comprise a computer program. The computer program product has, in particular, the program code which map the inventive method steps according to one or more example embodiments. As a result, the inventive method according to one or more example embodiments can be defined and repeatedly carried out and control can be exercised over transfer of the inventive method according to one or more example embodiments. The computer program product is preferably configured in such a way that the computing unit can carry out the inventive method steps according to one or more example embodiments via the computer program product. The program code can be loaded, in particular, into a memory of the computing unit and are typically executed via a processor of the computing unit with access to the memory. When the computer program product, in particular the program code, is executed in the computing unit, typically all inventive embodiments of the described method can be carried out. The computer program product is saved, for example, on a physical, computer-readable medium and/or stored digitally as a data packet in a computer network. The computer program product can represent the physical, computer-readable medium and/or the data packet in the computer network. The invention can thus also start from the physical, computer-readable medium and/or the data packet in the computer network. The physical, computer-readable medium can customarily be directly connected to the computing unit, for example by inserting the physical, computer-readable medium in a DVD drive or by plugging it into a USB port, whereby the computing unit can access, in particular read access, the physical, computer-readable medium. The data packet can preferably be retrieved from the computer network. The computer network can have the computing unit or be indirectly connected to the computing unit via a Wide Area Network (WAN) or a (Wireless) Local Area Network connection (WLAN or LAN). For example, the computer program product can be digitally stored on a Cloud-Server at a storage location of the computer network, can be transmitted via the WAN via the Internet and/or via the WLAN or LAN to the computing unit, in particular by calling up a download link which refers to the storage location of the computer program product.

Features, advantages or alternative embodiments mentioned in the description of the apparatus should also be transferred to the method, and vice versa. In other words, claims on the method can be developed with features of the apparatus, and vice versa. In particular, the inventive apparatus according to one or more example embodiments can be used in the method.

Independent of the grammatical term usage, individuals with male, female or other gender identities are included within the term.

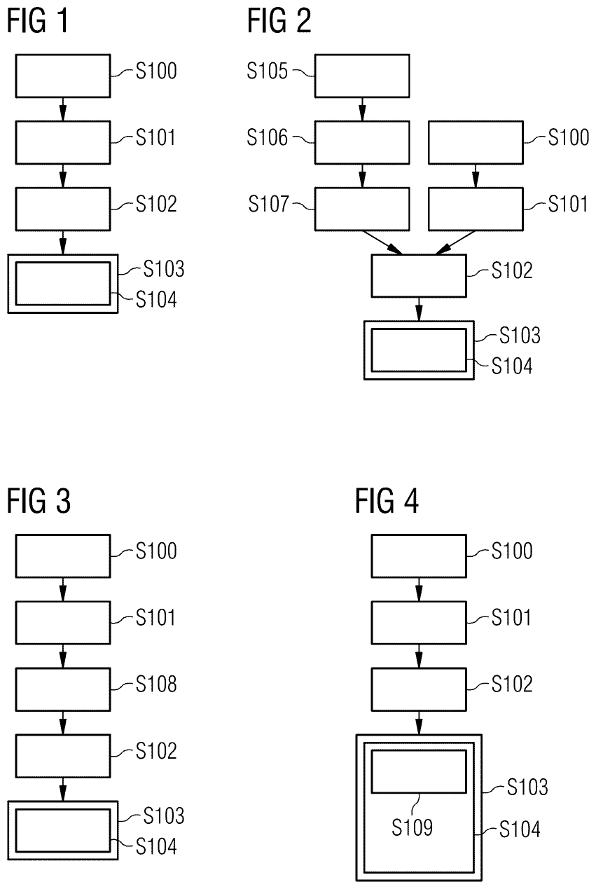

FIG. 1 shows an inventive method for carrying out an MRI examination of a patient via an MRI system according to one or more example embodiments in a flowchart comprising the steps S100 to S104:

Method step S100 denotes an adjustment of an examination parameter of the MRI examination to the patient via a control unit of the MRI system.

The adjusted examination parameter can specify a repetition time, an echo time and/or an echo spacing of the MRI examination, so the generated media signal depends on the repetition time and/or the echo time and/or the echo spacing. Alternatively or in addition, the examination parameter can specify one or more instant(s) and/or a total or remaining duration for the patient to remain lying down, hold their breath, stay still and/or relax, so the generated media signal depends on one or more instant(s) and/or a total or remaining duration to remain lying down, breath-hold, stay still and/or relax.

Method step S101 denotes a provision of the adjusted examination parameter via the control unit as an input parameter for a generative AI system, with the generative AI system being configured to generate a media signal as an output parameter in response to an input of the provided input parameter and to provide the generated media signal for retrieval, with the generated media signal depending on the adjusted examination parameter and comprising an audio track and/or a video track.

Method step S102 denotes reception of the generated media signal via a playback unit.

Method step S103 denotes a performance of the MRI examination of the patient in accordance with the adjusted MRI examination parameter via the MRI system in such a way that meanwhile, in accordance with method step S104, the received media signal is played via the playback unit for perception by the patient.

FIG. 2 shows a flowchart of a first exemplary embodiment of the method.

Method step S105 denotes that the patient is provided with a plurality of media signal content types for selection by the patient and an item of preference information individual to the patient comprises the media signal content type selected by the patient.

Method step S106 denotes reception of the item of preference information individual to the patient via the control unit.

Method step S107 denotes providing the received item of preference information individual to the patient as a further input parameter in addition to the adjusted examination parameter for the generative AI system, so the generated media signal also depends on the item of preference information individual to the patient.

FIG. 3 shows a flowchart of a second exemplary embodiment of the method.

Method step S108 denotes that the adjusted examination parameter is variable over time, so the audio track and/or the video track of the generated media signal are synchronized rhythmically and/or harmonically and/or in terms of image content via the AI system with the examination parameter which is variable over time.

FIG. 4 shows a flowchart of a third exemplary embodiment of the method.

Method step S109 denotes that the generated media signal comprises a video track, with the video track comprising a graphical representation of an individual for interaction with the patient in such a way that during the performance of the MRI examination, items of information are played to the patient via the represented individual as a function of the examination parameter.

FIG. 5 shows a flowchart of a fourth exemplary embodiment of the method.

Method step S110 denotes that the adjusted examination parameter comprises a total duration of the MRI examination, so the total duration of the media signal substantially corresponds to the total duration of the MRI examination.

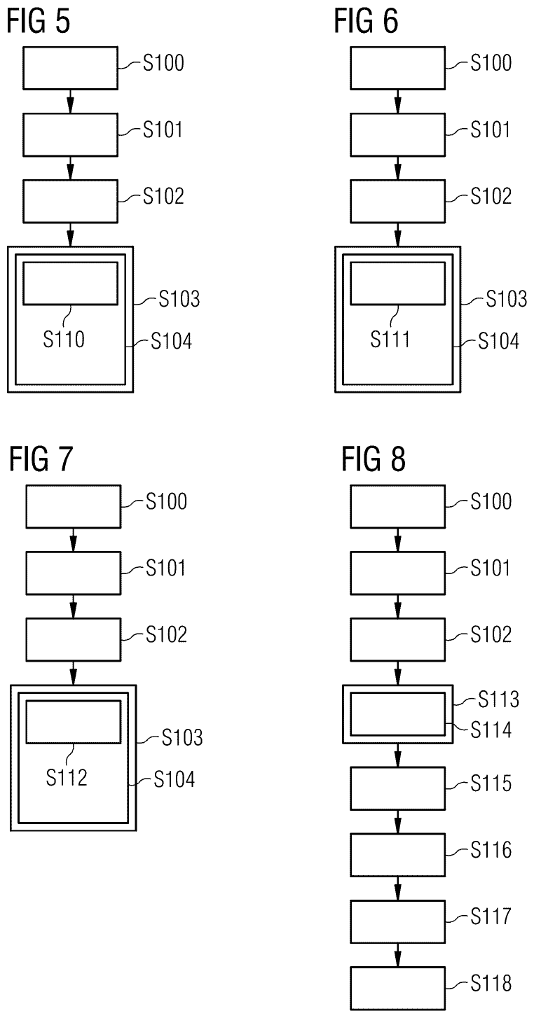

FIG. 6 shows a flowchart of a fifth exemplary embodiment of the method.

Method step S111 denotes that the generated media signal comprises an audio track, with the adjusted examination parameter comprising a gradient profile of at least one gradient coil of a magnetic unit of the MRI system, so the audio track of the generated media signal is rhythmically and/or harmonically synchronized with noise emissions of the gradient profile in such a way that the noise emissions are overlaid or integrated by the media signal which has been played.

FIG. 7 shows a flowchart of a sixth exemplary embodiment of the method.

Method step S112 denotes that the generated media signal comprises an audio track, with at least one gradient coil of the MRI system being energized as a playback unit to play the audio track of the media signal during performance of the MRI examination over at least part of the total duration of the generated media signal.

FIG. 8 shows a flowchart of a seventh exemplary embodiment of the method.

Method step S113 denotes the beginning of performance of the MRI examination.

Method step S114 denotes the beginning of playing of the received media signal in the meantime.

Method step S115 denotes that, after the beginning of the performance of the MRI examination, an examination parameter is re-adjusted.

Method step S116 denotes that the re-adjusted examination parameter is provided as an input parameter for the generative AI system, with the generative AI system being configured to adjust, in response to an input of the re-adjusted examination parameter which has been provided, the generated media signal to the re-adjusted examination parameter in order to generate an adjusted media signal and provide it for retrieval, with the adjusted media signal depending on the re-adjusted examination parameter and being based on the generated media signal.

Method step S117 denotes that playing is continued with the adjusted media signal as a replacement for the generated media signal for the remaining time of performance of the MRI examination.

Method step S118 denotes the end of playing of the received media signal and/or performance of the MRI examination.

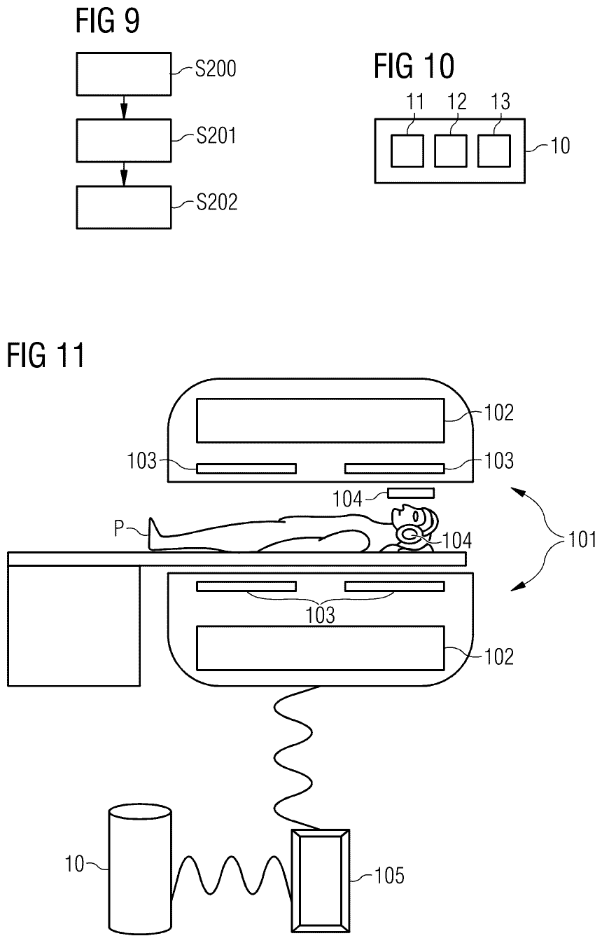

FIG. 9 shows a flowchart of a method for providing a media signal via an AI system.

Method step S200 denotes reception of an examination parameter of an MRI examination of a patient as an input parameter.

Method step S201 denotes generating a media signal as an output parameter in response to an input of the input parameter.

Method step S202 denotes provision of the generated media signal for retrieval, with the generated media signal depending on the adjusted examination parameter and comprising an audio track and/or a video track.

FIG. 10 shows a block diagram of an inventive AI system 10 according to one or more example embodiments.

The AI system 10 has an input interface 11 for receiving an input parameter. The AI system 10 also has a computer unit 12 for generating an output parameter as a function of the received input parameter by applying a generative AI model to the input parameter. The AI system 10 also comprises an output interface 13 for providing the generated output parameter. The AI system 10 is embodied, in particular trained, in particular to carry out a method in accordance with FIG. 9.

FIG. 11 shows a schematic representation of an inventive MRI system 100 according to one or more example embodiments.

The MRI system 100 has a magnetic unit 101. The magnetic unit 101 comprises a main magnet 102 and at least one gradient coil 103. The MRI system 100 also comprises a control unit 105 and in this exemplary embodiment optionally a playback unit 104.

The playback unit 104 comprises headphones for perception of an audio track of the generated media signal. The headphones are worn by the patient P. The playback unit 104 also comprises a display unit for perception of a video track of the generated media signal.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “on,” “connected,” “engaged,” “interfaced,” and “coupled.” Unless explicitly described as being “direct,” when a relationship between first and second elements is described in the disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” on, connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “example” is intended to refer to an example or illustration.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Specific structural and functional details disclosed herein are merely representative for purposes of describing example embodiments. The present invention may, however, be embodied in many alternate forms and should not be construed as limited to only the embodiments set forth herein.

In addition, or alternative, to that discussed above, units and/or devices according to one or more example embodiments may be implemented using hardware, software, and/or a combination thereof. For example, hardware devices may be implemented using processing circuitry such as, but not limited to, a processor, Central Processing Unit (CPU), a Graphics Processing Unit (GPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility (also referred to as a data processing facility) or computer device to execute the program of any of the above mentioned embodiments and/or to perform the method of any of the above mentioned embodiments.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

Although the invention has been illustrated and described in detail by the preferred exemplary embodiments, it is nevertheless not limited by the disclosed examples and a person skilled in the art can derive other variation herefrom without departing from the scope of the invention.

1. A method for carrying out an MRI examination of a patient via an MRI system, the method comprising:
adjusting an examination parameter of the MRI examination to the patient via a control unit of the MRI system;
providing the adjusted examination parameter via the control unit as an input parameter for a generative AI system, wherein the generative AI system is configured to generate a media signal as an output parameter in response to an input of the provided input parameter, wherein the generated media signal includes at least one of an audio track or a video track;
receiving the generated media signal via a playback unit; and
performing the MRI examination of the patient in accordance with the adjusted MRI examination parameter via the MRI system such that the received media signal is played via the playback unit for perception by the patient during the MRI examination.

2. The method of claim 1, further comprising:
receiving an item of preference information individual to the patient via the control unit; and
providing the received item of preference information individual to the patient as a further input parameter in addition to the adjusted examination parameter for the generative AI system such that the generated media signal also depends on the item of preference information individual to the patient.

3. The method of claim 2, further comprising:
providing the patient with a plurality of media signal content types for selection by the patient and the item of preference information individual to the patient comprises the media signal content type selected by the patient.

4. The method of claim 1, wherein the adjusted examination parameter is variable over time such that the least one of the audio track or the video track of the generated media signal are at least one of synchronized at least one of rhythmically or harmonically or in terms of image content via the AI system with the examination parameter.

5. The method of claim 1, wherein the generated media signal comprises a video track, and the video track comprises a graphical representation of an individual for interaction with the patient such that during performance of the MRI examination, items of information are played to the patient via the represented individual as a function of the examination parameter.

6. The method of claim 1, wherein the adjusted examination parameter comprises at least one of a repetition time, an echo time or an echo spacing of the MRI examination such that the generated media signal depends on at least one of the repetition time, the echo time, or the echo spacing.

7. The method of claim 1, wherein the examination parameter comprises at least one of (i) one or more instant(s) or (ii) a total or remaining duration,
for the patient to remain lying down, hold their breath, stay at least one of still or relax.

8. The method of claim 1, wherein the examination parameter comprises a total duration of the MRI examination such that the total duration of the media signal substantially corresponds to a total duration of the MRI examination.

9. The method of claim 1, wherein the generated media signal comprises an audio track, and the adjusted examination parameter comprises a gradient profile of at least one gradient coil of a magnetic unit of the MRI system such that the audio track of the generated media signal is at least one of rhythmically or harmonically synchronized with noise emissions of the gradient profile such that the noise emissions are overlaid or integrated by the media signal which has been played.

10. The method of claim 1, wherein after starting the performing of the MRI examination,
the adjusted examination parameter is re-adjusted,
the re-adjusted examination is provided as the input parameter for the generative AI system,
the generative AI system is configured to adjust the generated media signal in response to the provided re-adjusted examination parameter and provide the adjusted generated media signal for retrieval, wherein playing is continued with the adjusted media signal as a replacement for the generated media signal for a remaining time of the performing the MRI examination.

11. The method of claim 1, wherein the generated media signal comprises an audio track, at least one gradient coil of the MRI system is energized as a playback unit to play the audio track of the media signal during the performing the MRI examination over at least part of a total duration of the generated media signal.

12. A computer-implemented method for providing a media signal via an AI system, the method comprising:
receiving an examination parameter of an MRI examination of a patient as an input parameter;
generating a media signal as an output parameter in response to an input of the input parameter; and
providing the generated media signal for retrieval, wherein the generated media signal depends on an adjusted examination parameter and at least one of an audio track or a video track.

13. An AI system, comprising:
an input interface configured to receive an input parameter;
a computer unit configured to generate an output parameter as a function of the received input parameter by applying a generative AI model to the input parameter; and
an output interface configured to provide the generated output parameter,
wherein the AI system is configured to perform the method of claim 12.

14. An MRI system, comprising:
a magnetic unit, wherein the magnetic unit comprises a main magnet and at least one gradient coil; and
a control unit configured to cause the MRI system to perform the method of claim 1.

15. The MRI system of claim 14, further comprising:
an AI system including,
an input interface configured to receive an input parameter,
a computer unit configured to generate an output parameter as a function of the received input parameter by applying a generative AI model to the input parameter, and
an output interface configured to provide the generated output parameter.

16. A non-transitory computer readable medium comprising program code, when executed by a control unit, cause the control unit to perform the method of claim 1.

17. The method of claim 2, wherein the adjusted examination parameter is variable over time such that the least one of the audio track or the video track of the generated media signal are at least one of synchronized at least one of rhythmically or harmonically or in terms of image content via the AI system with the examination parameter.

18. The method of claim 2, wherein the generated media signal comprises a video track, and the video track comprises a graphical representation of an individual for interaction with the patient such that during performance of the MRI examination, items of information are played to the patient via the represented individual as a function of the examination parameter.

19. The method of claim 2, wherein the adjusted examination parameter comprises at least one of a repetition time, an echo time or an echo spacing of the MRI examination such that the generated media signal depends on at least one of the repetition time, the echo time, or the echo spacing.

20. The method of claim 2, wherein the examination parameter comprises a total duration of the MRI examination such that the total duration of the media signal substantially corresponds to a total duration of the MRI examination.
